(19) United States
(12) Patent Application Publication
(10) Pub. No.: US 2024/0304248 A1
(43) Pub. Date: Sep. 12, 2024

(54) MEMORY PROGRAMMING

(71) Applicant: YANGTZE MEMORY TECHNOLOGIES CO., LTD., Wuhan (CN)

(72) Inventor: Xiangnan ZHAO, Wuhan (CN)

(21) Appl. No.: 18/323,158

(22) Filed: May 24, 2023

(30) Foreign Application Priority Data
Mar. 8, 2023 (CN) 202310224104.X

(51) Int. Cl. G11C 16/10; G11C 16/34

(52) U.S. Cl. CPC G11C 16/10; G11C 16/3459; G11C 16/0483

(57) ABSTRACT

A method comprises: in a coarse programming process, performing programming suppression on first memory cells, such that the first memory cells are in a first programmed state; and performing pulse programming for i−1 times on second memory cells to program the second memory cells to an ith programmed state, where i>1, and the coarse programming process does not include programming verification. In the coarse programming process, by presetting a pulse programming period of a memory cell corresponding to each programmed state, distinguishing the corresponding number of programming of the memory cell corresponding to each programmed state and completing the programming of the memory cells, without performing a verification operation on a voltage reached by the memory cells after each pulse programming in the coarse programming process.

### CROSS-REFERENCE TO RELATED APPLICATIONS

This application claims the priority of Chinese Patent Application No. 202310224104.X, filed on Mar. 8, 2023, titled “Programming Method for Memory, Memory, and Storage System,” and incorporated herein by reference in its entirety.

### TECHNICAL FIELD

The present disclosure relates to the technical field of storage, and in particular to programming of a memory, a memory and a storage system.

### BACKGROUND

A 3-dimension (3D) memory includes a plurality of memory cells, and types of the memory cells may be divided into single-level cells (SLC), multi-level cells (MLC), trinary-level cells (TLC), and quaternary-level cell (QLC), etc. according to an amount of data capable of being stored by the memory cells.

Various memory cells on the same layer may constitute a page. Taking a QLC as an example, in order to achieve four-bit storage, one page is to be divided into 16 programmed states, and multiple programming writes are performed on each page. For example, a coarse programming write is first performed, and then a fine programming write is performed. SUMMARY

The present disclosure provides a method of programming a memory, a memory and a storage system, which may improve the programming efficiency of programming a memory.

In one aspect, a method of programming a memory through a programming operation having a coarse programming process and fine programming process is provided. The method comprises performing programming suppression on first memory cells in the coarse programming process, such that the first memory cells are in a first programmed state, and performing pulse programming for i−1 times on second memory cells to program the second memory cells to an ith programmed state in the coarse programming process, where i>1 and the coarse programming process does not include programming verification.

In one optional implementation, the method further comprises determining a number n of programmed states divided in the coarse programming process, where n≥i, and applying n−1 programming pulses to a page in the memory based on the number n of the programmed states divided in the coarse programming process, the first memory cells and the second memory cells being memory cells in the page.

In one optional implementation, performing the pulse programming for i−1 times on the second memory cells to program the second memory cells to the ith programmed state comprises performing the pulse programming on the second memory cells at first i−1 programming pulses of the n−1 programming pulses to program the second memory cells to the ith programmed state.

In one optional implementation, the method further comprises performing programming suppression on the second memory cells in a pulse programming process starting from an ith programming pulse in response to a number i of programming pulses applied to the page not reaching n−1.

In one optional implementation, prior to performing the pulse programming for n−1 times on the page in the memory based on the number n of the programmed states divided in the coarse programming process, the method further comprises applying a first voltage to word lines coupled to the memory cells in the page, performing programming verification on the memory cells in the page, and classifying the memory cells into a fast programming type and a slow programming type based on a threshold voltage of the memory cells. Performing the pulse programming for i−1 times on the second memory cells to program the second memory cells to the ith programmed state comprises performing pulse programming for i−1 times on the second memory cells to program the second memory cells to the ith programmed state based on a memory cell type of the second memory cells.

In one optional implementation, performing the pulse programming for i−1 times on the second memory cells to program the second memory cells to the ith programmed state based on the memory cell type of the second memory cells comprises applying a second voltage to bit lines coupled to the second memory cells, and applying a programming voltage to word lines coupled to the second memory cells to perform the pulse programming for i−1 times to program the second memory cells to the ith programmed state in response to the second memory cells corresponding to the fast programming type. In the case that the second memory cells correspond to the slow programming type, applying a third voltage to bit lines coupled to the second memory cells, and applying a programming voltage to word lines coupled to the second memory cells to perform the pulse programming for i−1 times to program the second memory cells to the ith programmed state, wherein the second voltage is higher than the third voltage.

In one optional implementation, performing the pulse programming for i−1 times on the second memory cells to program the second memory cells to the ith programmed state based on the memory cell type of the second memory cells comprises applying a fourth voltage to bit lines coupled to the second memory cells at a first stage of a kth pulse programming, and applying a fifth voltage to the bit lines coupled to the second memory cells at a second stage of the kth pulse programming, and applying a programming voltage to word lines coupled to the second memory cells to program the second memory cells to the ith programmed state in response to the second memory cells corresponding to the fast programming type, the fourth voltage being higher than the fifth voltage, where 0<k<i. In the case that the second memory cells correspond to the slow programming type, applying the fifth voltage to bit lines coupled to the second memory cells, and applying a programming voltage to word lines coupled to the second memory cells to perform the pulse programming for i−1 times to program the second memory cells to the ith programmed state.

In another aspect, a memory is provided. The memory is programmable via a programming operation having coarse programming and fine programming. The memory comprises an array and a peripheral circuit. The peripheral circuit is configured to perform programming suppression on first memory cells of the array in the coarse programming process such that the first memory cells are in a first programmed state, and perform pulse programming for i−1 times on second memory cells of the array to program the second memory cells to an ith programmed state in the coarse programming process, where i>1. The coarse programming process does not include programming verification.

In one optional implementation, the peripheral circuit is further configured to determine a number n of programmed states divided in the coarse programming process, where n≥i, and apply programming pulses for n−1 times to a page in the memory based on the number n of the programmed states divided in the coarse programming process. The first memory cells and the second memory cells are memory cells in the page.

In one optional implementation, the peripheral circuit is further configured to perform the pulse programming on the second memory cells at first i−1 programming pulses of the n−1 programming pulses to program the second memory cells to the ith programmed state.

In one optional implementation, the peripheral circuit is further configured to perform programming suppression on the second memory cells in a pulse programming process starting from an ith programming pulse in response to a number i of programming pulses applied to the page not reaching n−1.

In one optional implementation, the peripheral circuit is further configured to apply a first programming pulse to word lines coupled to memory cells in the page, perform programming verification on the memory cells in the page, and classify the memory cells into a fast programming type and a slow programming type based on a threshold voltage of the memory cells. The peripheral circuit is further configured to perform pulse programming for i−1 times on the second memory cells to program the second memory cells to the ith programmed state based on a memory cell type of the second memory cells.

In one optional implementation, the peripheral circuit is further configured to apply a second voltage to bit lines coupled to the second memory cells, and apply a programming voltage to word lines coupled to the second memory cells to perform the pulse programming for i−1 times to program the second memory cells to the ith programmed state in response to the second memory cells corresponding to the fast programming type. The peripheral circuit is further configured to apply a third voltage to bit lines coupled to the second memory cells, and apply a programming voltage to word lines coupled to the second memory cells to perform the pulse programming for i−1 times to program the second memory cells to the ith programmed state in response to the second memory cells corresponding to the slow programming type. The second voltage is higher than the third voltage.

In one optional implementation, the peripheral circuit is further configured to apply a fourth voltage to bit lines coupled to the second memory cells at a first stage of a kth pulse programming, and apply a fifth voltage to the bit lines coupled to the second memory cells at a second stage of the kth pulse programming. In the case that the second memory cells correspond to the fast programming type, apply a programming voltage to word lines coupled to the second memory cells to program the second memory cells to the ith programmed state, where the fourth voltage is higher than the fifth voltage, and 0<k<i. The peripheral circuit is further configured to apply the fifth voltage to bit lines coupled to the second memory cells, and apply a programming voltage to word lines coupled to the second memory cells to perform the pulse programming for i−1 times to program the second memory cells to the ith programmed state, in response to the second memory cells corresponding to the slow programming type.

In another aspect, a system is provided, which comprises: one or more memories as described in the above implementations, and a memory controller coupled to the memories and configured to control the memories.

Implementations described herein provide various technical advantages. In the coarse programming process, by presetting a pulse programming period of a memory cell corresponding to each programmed state, the corresponding number of programming operations of the memory cell corresponding to each programmed state and completing the programming of the memory cells are performed without performing a verification operation on a voltage reached by the memory cells after each pulse programming in the coarse programming process. Omitting the verification operation in coarse programming improves the efficiency of the coarse programming by reducing the time consumption of the coarse programming.

### BRIEF DESCRIPTION OF THE DRAWINGS

The drawings to be used in description of implementations will be briefly introduced below in order to illustrate the technical solutions in the implementations of the present disclosure more clearly. The drawings described below are only some implementations of the present disclosure. Those of ordinary skill in the art may obtain other drawings according to these drawings without creative work.

FIG. 1 is a schematic structural diagram of a 3D memory provided by a schematic implementation of the present disclosure.

FIG. 2 is a schematic diagram of increment step pulse programming provided by a schematic implementation of the present disclosure.

FIG. 3 is a schematic process diagram of 16-16 two-step programming provided by an implementation of the present disclosure.

FIG. 4 is a schematic process diagram of 8-16 two-step programming provided by an implementation of the present disclosure.

FIG. 5 is a schematic process diagram of 4-16 two-step programming provided by an implementation of the present disclosure.

FIG. 6 is a flow diagram of a programming method of a memory provided by an implementation of the present disclosure.

FIG. 7 is a schematic diagram of pulse programming voltage application provided by an implementation of the present disclosure.

FIG. 8 is a flow diagram of a programming method of a memory provided by another implementation of the present disclosure.

FIG. 9 is a schematic diagram of pulse programming voltage application of fast and slow programming types provided by an implementation of the present disclosure.

FIG. 10 is a schematic diagram of pulse programming voltage application of fast and slow programming types provided by another implementation of the present disclosure.

FIG. 11 is a schematic structural diagram of a memory provided by an implementation of the present disclosure.

FIG. 12 is a schematic structural diagram of a storage system provided by an implementation of the present disclosure.

### DETAILED DESCRIPTION

Implementations of the present disclosure are further described below in detail in conjunction with the drawings.

A programming method of a memory provided by the implementations of the present disclosure may be applied to a memory. The memory may be a 3D memory, for example, such as a 3D NAND flash memory.

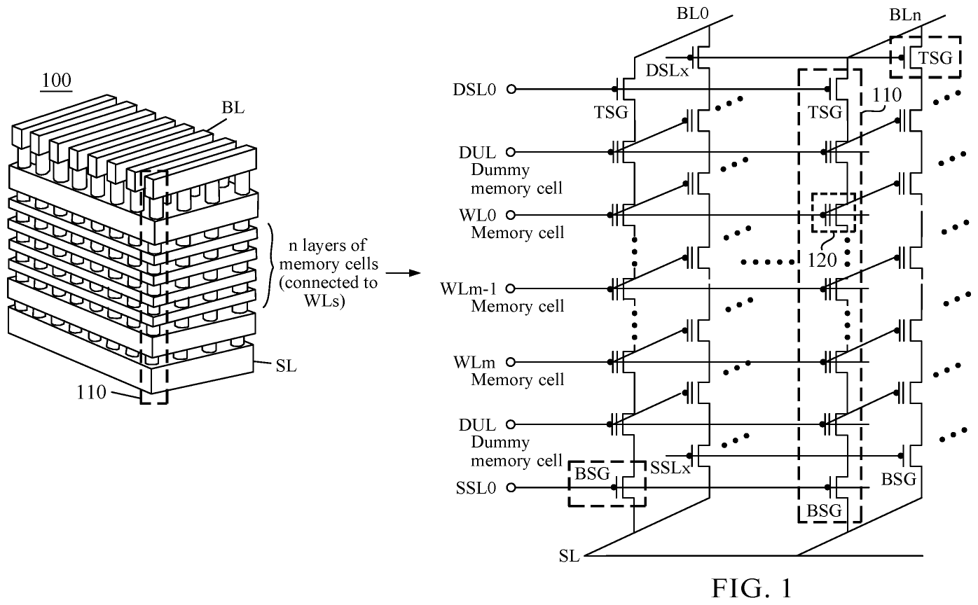

A 3D memory is a multi-layer stacked memory. As shown in FIG. 1, the 3D memory 100 is a 3D NAND flash memory. A plurality of memory strings 110 included in the 3D memory 100 are distributed along a direction parallel to a bearing surface of a substrate, and a plurality of memory cells 120 in each memory string 110 are distributed along a direction perpendicular to the bearing surface of the substrate. For example, the plurality of memory cells 120 included in the 3D memory 100 are distributed in a three-dimensional array on the substrate, and form an array.

The memory strings 110 are connected with bit lines (BL) at one end, and connected with source lines (SL) at the other end.

The memory cells 120 in each memory string 110 are further connected with the memory cells 120 in other memory strings 110 through word lines (WL). For example, each memory string 110 may comprise 64 memory cells 120, such that the 3D memory 100 may comprise 64 word lines WL <63:0>, and each word line is connected with part of the memory cells 120 on the same layer (i.e., having the same height relative to the substrate). It is noted that the 64 memory cells 120 are only an example, the present disclosure is not limited to this, and in some implementations, each memory string 110 may comprise more than 64 (e.g., 128, 196, etc.) memory cells 120. In the 3D memory 100, various memory cells 120 connected with the same word line are referred to as a page, and all the memory strings 110 sharing a set of word lines are referred to as a block.

The memory strings 110 further comprise upper select transistors connected with drains of first memory cells 120, and lower select transistors connected with sources of last memory cells 120. The upper select transistors are also called top select gates (TSG) or drain select transistors. The lower select transistors are also called bottom select gates (BSG) or source select transistors.

Gates of the TSGs are connected with drain select lines (DSL), sources of the TSGs are connected with the drains of the first memory cells 120, and drains of the TSGs are connected with the bit lines.

Gates of the BSGs are connected with source select lines (SSL), drains of the BSGs are connected with sources of the last memory cells 120, and sources of the BSGs are connected with the source lines.

As can be seen from FIG. 1, the memory cells 120 in the memory string 110 and the memory cells 120 in other memory strings 110 share a set of WLs. In an example, each memory string 110 comprises m+1 memory cells 120, such that the 3D memory 100 may comprise m+1 WLs: WL0 through WLm, where m is an integer greater than 1. Each WL is connected with various memory cells 120 on the same layer (i.e., having the same height relative to the bearing surface of the substrate). Alternatively, control gates of various memory cells 120 on the same layer, and a gate connection line between various control gates, constitute one WL.

The types of the memory cells 120 may be divided into single-level cells (SLC), multi-level cells (MLC), trinary-level cells (TLC), and quaternary-level cell (QLC), etc. according to an amount of data capable of being stored by the memory cells 120. Each SLC can store 1 bit of data, each MLC can store 2 bits of data, each TLC can store 3 bits of data, and each QLC can store 4 bits of data. In the 3D memory 100, the data stored in various memory cells 120 on the same layer may constitute k pages, where k is the number of bits of data capable of being stored by each memory cell 120.

In the implementations of the present disclosure, the memory cells 120 in the 3D memory 100 may be field effect transistors capable of storing data, such as floating gate field effect transistors or charge trap field effect transistors, etc. The TSGs and the BSGs may be either ordinary field effect transistors, or field effect transistors capable of storing data. The floating gate field effect transistor comprises a source, a drain and two gates. The two gates are conductors, and one of the two gates is a control gate (CG), and the other one is a floating gate (FG). The control gate is used to connect the word lines, and the floating gate is used to store data. The charge trap field effect transistors comprise sources, drains, control gates and charge trap layers, where the charge trap layers are cells for storing data and are made of insulating materials, such as silicon nitride. A data writing principle of the memory cells is described below, taking the floating gate field effect transistors as an example.

When data is written to the memory cells 120, a programming voltage may be loaded to control gates of the floating gate field effect transistors to cause electrons in channels of the floating gate field effect transistors to tunnel to floating gates. The number of electrons tunneling to the floating gates can be controlled by controlling a magnitude of the programming voltage, so as to control a magnitude of a threshold voltage (Vth) of the floating gate field effect transistors. Generally, the higher the quantity of charge stored in the floating gates is, the higher the threshold voltage of the floating gate field effect transistors is. When the threshold voltages of the floating gate field effect transistors are different, the voltages to be loaded to the control gates of the floating gate field effect transistors to control the floating gate field effect transistors to turn on are different. Therefore, the magnitude of the threshold voltage of the floating gate field effect transistors may reflect contents of data stored by them.

In the 3D memory 100, channels of various memory cells in each memory string can be connected sequentially, and form a pillar-shaped structure perpendicular to the substrate.

In some examples, a programming mode employed in the programming of the 3D memory 100 is an increment step pulse programming (ISPP) mode. A voltage is not applied all at once when the programming voltage is applied in a programming process. Instead, the programming voltage is increased step by step incrementally.

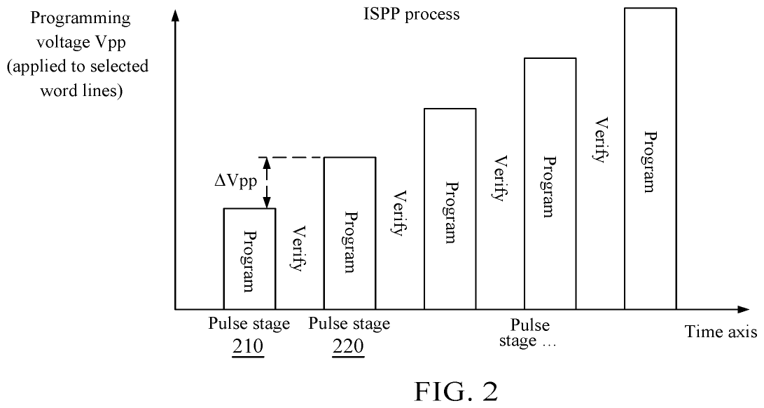

FIG. 2 illustrates a schematic diagram of ISPP provided by one implementation of the present disclosure. As shown in FIG. 2, the programming process includes a programming stage and a verification stage. For a NAND type memory, a write operation is performed in pages when the write operation is performed using the increment step pulse programming. By taking some memory cell in one page as an example, at a first programming pulse stage 210, a start programming voltage (Vpgm) is loaded to a word line coupled to the memory cell, and then a programming verification voltage (Vvf0) is loaded to the word line coupled to the memory cell to verify whether it is programmed to a target threshold voltage. If the target threshold voltage is not reached, it is programmed with a voltage higher than the start programming voltage by a preset voltage (Vpp) at a second programming pulse stage 220, and then a programming verification voltage (Vvf1) is loaded to verify whether it is programmed to the target threshold voltage. The above process is repeated until the threshold voltage of the memory cell is found to have been programmed to reach the target threshold voltage in a verification step. At such time, the programming of the memory cell is finished. At a subsequent time, a programming suppression voltage is applied to the bit line coupled to the memory cell to cause it not to be programmed any longer, and when the threshold voltages of all of the memory cells on this page are programmed to the target threshold voltage, the programming process of the whole page ends. A narrower final threshold voltage distribution may be obtained by programming through the above increment step pulse programming mode.

When the programming is performed on the memory, for example, the MLC may be configured to store two digits of data represented by four Vth ranges (programmed states) per memory cell, the TLC may be configured to store three digits of data represented by eight Vth ranges (programmed states) per memory cell, the QLC may be configured to store four digits of data represented by sixteen Vth ranges (programmed states) per memory cell, and so on.

For example, when a 3D NAND flash is an MLC flash, the memory cells of the 3D NAND flash may be programmed into four states corresponding to bit codes 11, 10, 01 and 00, e.g., an erased state E0, and programmed states P1, P2 and P3. In another implementation, when a 3D NAND flash is a TLC 3D NAND flash, the memory cells of the 3D NAND flash may be programmed into eight programmed states corresponding to bit codes 111, 110, 010, 011, 001, 000, 100 and 101.

In some examples, 3D NAND flash has increased storage capacity compared to non-3D NAND flash. To provide higher storage density, the number of stack layers and the number of storage bits of a single memory cell in the 3D NAND flash may be increased. As described above, a single memory cell may store four bits, such as a QLC. To provide four-bit storage, one page is divided into 16 programmed states. To compress a threshold voltage distribution width of each programmed state on the page, and increase a read window, multiple write operations are performed on the page, which are called coarse programming and fine programming. However, the process of coarse programming is also implemented by ISPP. As a result, a programming voltage of a certain pulse width is applied at each pulse stage in the ISPP for programming, and verification is performed through a verification voltage after the programming voltage is applied. The resulting time consumption of the coarse programming process may be long, resulting in reduced programming efficiency.

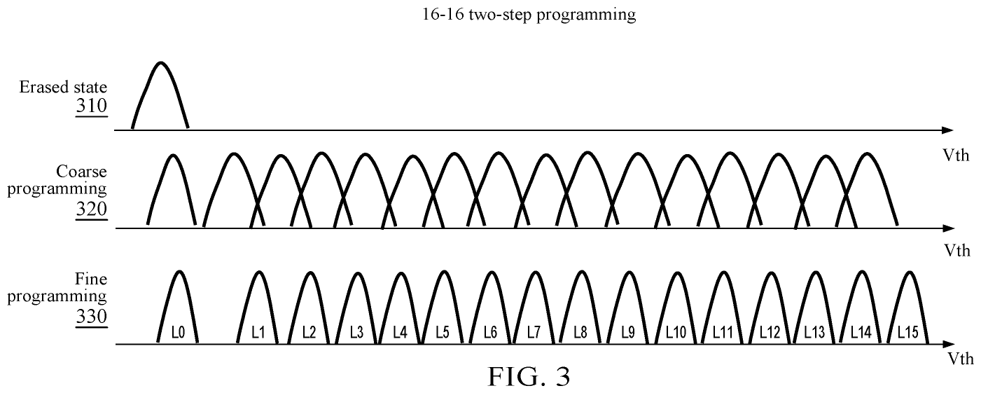

In a write process, the page may be coarsely programmed to 16 programmed states first, and then 16 final programmed states are finely programmed from the 16 programmed states. Referring to FIG. 3, in a 16-16 two-step programming process, an erased state 310 exists first, then a coarse programming 320 is performed on the page to obtain 16 programmed states with wide threshold voltage distribution widths, and a fine programming 330 is performed on the page based on the coarse programming 320 to compress the threshold voltage distribution width of each programmed state.

However, to reduce the programming time, 16 programmed states may not be programmed during the coarse programming. Instead, n programmed states (n<16) are programmed. For example, 8 programmed states may be coarsely programmed first, and then 16 programmed states are finely programmed from the 8 programmed states.

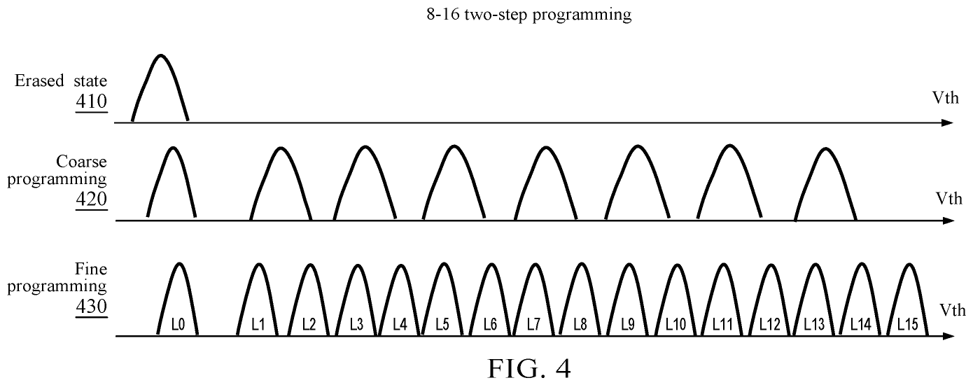

Referring to FIG. 4, in a 8-16 two-step programming process, an erased state 410 exists first, then a coarse programming 420 is performed on the page to obtain 8 programmed states with wide threshold voltage distribution widths, and a fine programming 430 is performed on the page based on the coarse programming 420 to compress the threshold voltage distribution width of each programmed state on the page, and 16 programmed states on the page are obtained.

To further reduce the programming time, 4 programmed states may be coarsely programmed first, and then 16 programmed states are finely programmed from the 4 programmed states.

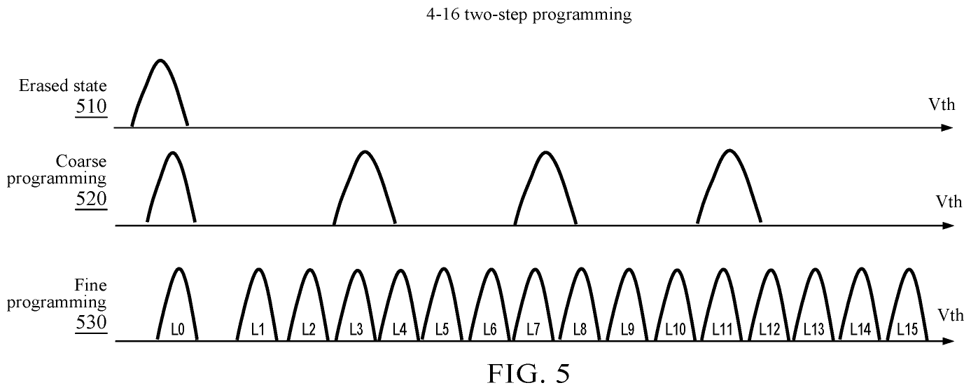

Referring to FIG. 5, in a 4-16 two-step programming process, an erased state 510 exists first, then a coarse programming 520 is performed on the page to obtain 4 programmed states with wide threshold voltage distribution widths, and a fine programming 530 is performed on the page based on the coarse programming 520 to compress the threshold voltage distribution width of each programmed state on the page, and 16 programmed states on the page are obtained.

However, even in the above approaches that reduce programming time, the coarse programming 520 occupies part of the programming time, resulting in the reduction of the programming efficiency.

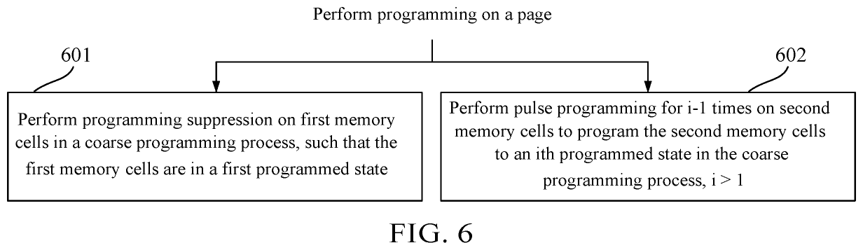

In the implementations of the present disclosure, a programming method is provided to further reduce programming time. Referring to FIG. 6, a flow diagram of a programming method of a memory provided by one implementation of the present disclosure is shown. The method comprises the following steps.

At step 601, programming suppression is performed on first memory cells in a coarse programming process, such that the first memory cells are in a first programmed state.

The coarse programming process does not include programming verification. For example, the programming verification is omitted during the coarse programming, and only a programming operation is performed.

The coarse programming process is a programming process performed for a designated page in the memory, the first memory cells are one or more memory cells in the designated page, and the first programmed state indicates an L0 programmed state, e.g., an erased state.

In the coarse programming process, the programming suppression is performed on the first memory cell. For example, no pulse programming is performed on the first memory cells, such that the first memory cells are in the first programmed state, e.g., the erased state, after the coarse programming.

At step 602, pulse programming is performed for i−1 times on second memory cells to program the second memory cells to an ith programmed state, where i>1.

The second memory cells are memory cells other than the first memory cells in the page. The first memory cells are memory cells in the first programmed state, and the second memory cells are memory cells in other programmed states. The second memory cells are memory cells to be programmed to an L1 programmed state, or the second memory cells are memory cells to be programmed to an L2 programmed state or a higher programmed state, and this implementation does not impose limitations to those. Because the L0 erased state corresponds to the first programmed state in this implementation, the L1 programmed state corresponds to a second programmed state in this implementation, the L2 programmed state corresponds to a third programmed state in this implementation, and so on.

In some implementations, a number n of programmed states divided in the coarse programming process is first determined, where n≥i, and n−1 programming pulses are applied to a page in the memory based on the number n of the programmed states divided in the coarse programming process, wherein the first memory cells and the second memory cells are memory cells in the page. For example, if the number of the programmed states divided in the coarse programming process corresponding to the page is n, programming pulses are performed n−1 times on the page. In the n−1 programming pulses, pulse programming for i−1 times is performed on the second memory cells to be programmed to the ith programmed state.

Taking an MLC as an example, the page corresponding to the MLC has 4 programmed states after fine programming, thus at a coarse programming stage 2 or 4 programmed states can be determined. Taking 2 programmed states, e.g., an L0 erased state and an L1 programmed state, as an example, 1 programming pulse is applied to the page in the memory at the coarse programming stage, wherein programming suppression is performed on the first memory cells corresponding to L0, and 1 programming pulse is applied to the second memory cells corresponding to L1. Taking 4 programmed states, e.g., an L0 erased state, an L1 programmed state, an L2 programmed state and an L3 programmed state, as an example, 3 programming pulses are applied to the page in the memory at the coarse programming stage, wherein programming suppression is performed on the first memory cells corresponding to the first programmed state L0 (e.g., the erased state), 1 programming pulse is applied to the second memory cells corresponding to the second programmed state L1, 2 programming pulses are applied to the second memory cells corresponding to the third programmed state L2, and 3 programming pulses are applied to the second memory cells corresponding to the fourth programmed state L3.

Taking a QLC as an example, the page corresponding to the QLC has 16 programmed states after fine programming, thus at a coarse programming stage, 2, 4, 8 or 16 programmed states can be determined. Taking 8 programmed states, e.g., an L0 erased state, an L1 programmed state, an L2 programmed state, an L3 programmed state, an L4 programmed state, an L5 programmed state, an L6 programmed state and an L7 programmed state, as an example, 7 programming pulses are applied to the page in the memory at the coarse programming stage. Programming suppression is performed on the first memory cells corresponding to the first programmed state L0 (e.g., the erased state), 1 programming pulse is applied to the second memory cells corresponding to the second programmed state L1, 2 programming pulses are applied to the second memory cells corresponding to the third programmed state L2, 3 programming pulses are applied to the second memory cells corresponding to the fourth programmed state L3, 4 programming pulses are applied to the second memory cells corresponding to the fifth programmed state L4, 5 programming pulses are applied to the second memory cells corresponding to the sixth programmed state L5, 6 programming pulses are applied to the second memory cells corresponding to the seventh programmed state L6, and 7 programming pulses are applied to the second memory cells corresponding to the eighth programmed state L7.

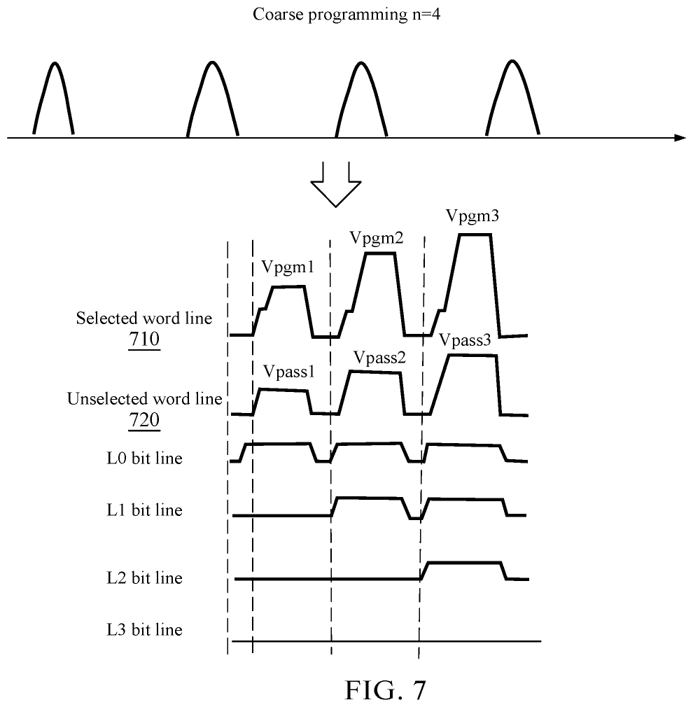

Referring to FIG. 7, for the page to be programmed to 4 programmed states (e.g., n=4) at the coarse programming stage, a programming voltage Vpgm is applied to a selected word line 710 coupled to the memory cells in the page and the programming voltage Vpgm is increased step by step incrementally in an ISPP manner. A voltage Vpass is applied to an unselected word line 720, where 3 voltages are applied to an L0 bit line coupled to the memory cells maintaining an L0 erased state. The programming suppression is performed on the memory cells maintaining the L0 erased state. 2 voltages are applied to an L1 bit line coupled to the memory cells for programming to an L1 programmed state for two programming suppressions. 1 voltage is applied to an L2 bit line coupled to the memory cells for programming to an L2 programmed state for two programming suppressions. A low voltage is applied to an L3 bit line coupled to the memory cells for programming to an L3 programmed state to not perform the programming suppression.

While the above coarse programming process is one example, the implementations of the present disclosure do not impose limitations to the number of programmed states at the coarse programming stage. The number of the programmed states at the coarse programming stage may also be randomly determined within the range of the total number of the programmed states.

In one optional implementation, for the second memory cells to be programmed to the ith programmed state, pulse programming may be performed on the second memory cell at a first i−1 programming pulses of n−1 programming pulses, or pulse programming may be performed on the second memory cells at a last i−1 programming pulses of the n−1 programming pulses, or pulse programming may be performed on the second memory cells at any i−1 programming pulses of the n−1 programming pulses, and this implementation does not impose limitations to those.

In implementations in which the pulse programming is performed on the second memory cells at any i−1 programming pulses of the n−1 programming pulses, the (i−1) th pulse programming the second memory cell from n−1 programming pulses may be determined by a random algorithm.

Taking performing the pulse programming on the second memory cells at first i−1 programming pulses of the n−1 programming pulses as an example, the pulse programming is performed on the second memory cells at the first i−1 programming pulses of the n−1 programming pulses to program the second memory cell to the ith programmed state. In an example in which the number of programming pulses applied to the page does not reach n−1, the programming suppression is performed on the second memory cells in a pulse programming process starting from an ith programming pulse.

In the coarse programming process, by presetting a pulse programming period of the memory cell corresponding to each programmed state, distinguishing the corresponding number of programming of the memory cell corresponding to each programmed state, and completing the programming of the memory cells, without performing the verification operation on the voltage reached by the memory cells after each pulse programming in the coarse programming process, the programming method provided by the implementations of the present disclosure improves the efficiency of the coarse programming and reduces the programming time consumption of the coarse programming.

In some examples, the method provided by this implementation improves the efficiency of distinguishing the numbers of coarse programming pulses of various second memory cells by performing the coarse programming on the second memory cells at first i−1 programming pulses of n−1 programming pulses.

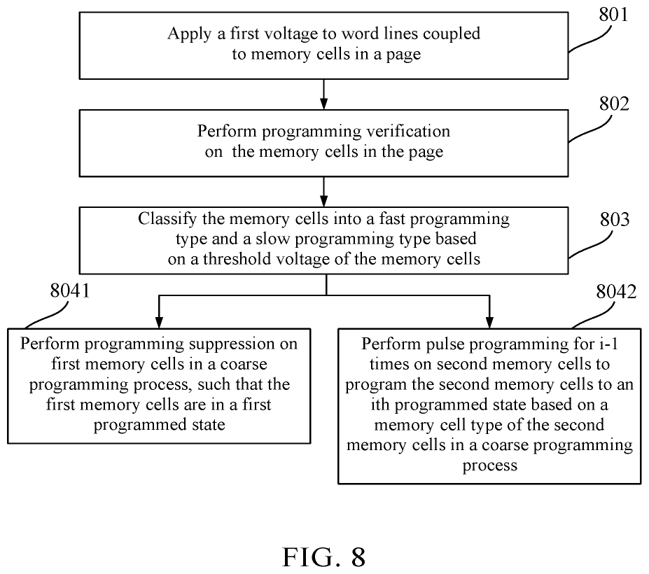

In one optional implementation, the memory cells may also be correspondingly distinguished as a fast programming type and a slow programming type. Referring to FIG. 8, a flow diagram of a programming method provided by another implementation of the present disclosure is shown. The method comprises the following steps.

At step 801, apply a first voltage to word lines coupled to memory cells in a page.

Optionally, before coarse programming, a first programming pulse voltage is applied to the word lines coupled to the memory cells in the page, wherein the first programming pulse voltage is a pulse voltage with a low voltage less than a voltage threshold. In some implementations, the word lines coupled to the memory cells to be maintained in the L0 erased state do not receive disclosure of the first programming pulse voltage. For example, the first programming pulse voltage, e.g., the above first voltage, is applied to word lines coupled to other memory cells than the memory cells corresponding to the L0 erased state.

Optionally, the first programming pulse voltage is a preset voltage, and is used to distinguish memory cell types of the memory cells. Schematically, a 1 V voltage is applied to the word lines coupled to the memory cells in the page as the first programming pulse voltage.

At step 802, perform programming verification on the memory cells in the page.

The programming verification is a verify stage performed before the coarse programming process and after applying the first programming pulse voltage. The coarse programming process does not include programming verification.

Optionally, the programming verification is performed on the memory cells in the page, e.g., a threshold voltage reached by the memory cells in the page after the first programming pulse voltage is applied is determined. For example, programming speeds of the memory cells at the same programming pulse voltage are determined according to the threshold voltage reached by the memory cells after the first programming pulse voltage is applied.

Optionally, one or more programming verifications are performed on the memory cells to determine the threshold voltage Vth reached by the memory cells.

At step 803, classify the memory cells into a fast programming type and a slow programming type based on a threshold voltage of the memory cells.

In some implementations, whether the memory cells belong to the fast programming type or the slow programming type is determined according to a relationship between the threshold voltage reached by the memory cells after the first programming pulse is applied and a reference threshold voltage.

For example, a 1 V voltage is applied to the word lines coupled to the memory cells in the page as the first programming pulse voltage, and the reference threshold voltage is determined as Vth0. After the programming verification is performed on the memory cells, if the threshold voltage Vth reached by the memory cells is greater than or equal to Vth0, the memory cells are determined as the fast programming type. Otherwise, if the threshold voltage Vth reached by the memory cells is less than Vth0, the memory cells are determined as the slow programming type. The above first programming pulse voltage and threshold voltage are examples, and the implementations of the present disclosure do not impose limitations to specific values of the voltages. In some implementations, the threshold voltage distribution of the programming verification is Gaussian distribution, with a maximum threshold voltage Vthmax and a minimum threshold voltage Vthmin. In some implementations, the reference threshold voltage Vth0 is between Vthmax and Vthmin. In some implementations, a value of the reference threshold voltage Vth0 is an intermediate value of Vthmax and Vthmin, e.g., (Vthmax+Vthmin)/2.

At step 8041, perform programming suppression on first memory cells in a coarse programming process, such that the first memory cells are in a first programmed state.

At step 8042, in a coarse programming process, perform pulse programming for i−1 times on second memory cells based on a memory cell type of the second memory cells to program the second memory cells to an ith programmed state.

In some implementations, performing coarse programming on the second memory cells based on the memory cell type of the second memory cells includes at least one of the following manners:

First, a programming speed of the pulse programming for i−1 times is intervened by a manner of applying a voltage to bit lines coupled to the second memory cells.

Optionally, a second voltage is applied to the bit lines coupled to the second memory cells, and a programming voltage is applied to word lines coupled to the second memory cells to perform the pulse programming for i−1 times to program the second memory cells to the ith programmed state in response to the second memory cells corresponding to the fast programming type.

A third voltage is applied to the bit lines coupled to the second memory cells, and a programming voltage is applied to the word lines coupled to the second memory cells to perform the pulse programming for i−1 times to program the second memory cells to the ith programmed state in response to the second memory cells corresponding to the slow programming type.

The second voltage is higher than the third voltage. For example, the higher second voltage is applied to the bit lines coupled to the second memory cells to suppress the programming speed of the second memory cells to avoid overprogramming of the second memory cells in response to the second memory cells corresponding to the fast programming type, while the lower third voltage is applied to the bit lines coupled to the second memory cells to provide normal programming of the second memory cells in response to the second memory cells corresponding to the slow programming type.

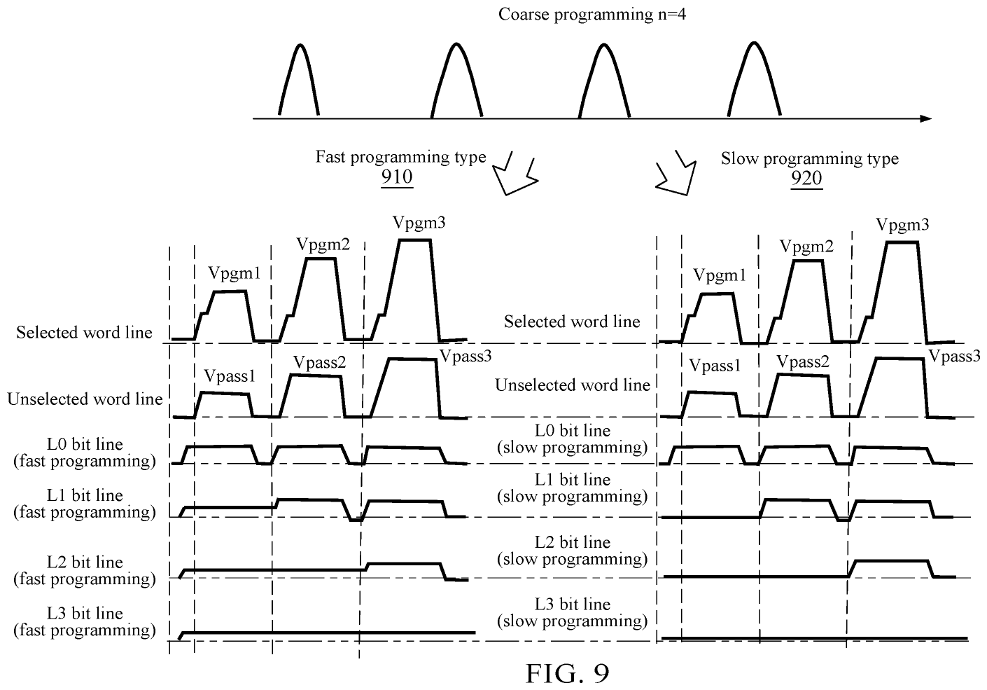

Referring to FIG. 9, when the second memory cells correspond to a fast programming type 910, if the second memory cells are to be programmed to an L1 programmed state, the second voltage is applied to an L1 bit line coupled to the second memory cells at the programming pulse stage of the second memory cells, where the second voltage Vbl2 is any voltage in a preset voltage interval or a preset voltage. If the second memory cells are to be programmed to an L2 programmed state, the second voltage is applied to an L2 bit line coupled to the second memory cells at two programming pulse stages of the second memory cells. If the second memory cells are to be programmed to an L3 programmed state, the second voltage Vbl2 is applied to an L3 bit line coupled to the second memory cells at three programming pulse stages of the second memory cells.

When the second memory cells correspond to a slow programming type 920, if the second memory cells are to be programmed to the L1 programmed state, the third voltage Vbl3 is applied to the L1 bit line coupled to the second memory cells at the programming pulse stage of the second memory cells, where the third voltage Vbl3 is 0 V. If the second memory cells are to be programmed to the L2 programmed state, the third voltage Vbl3 is applied to the L2 bit line coupled to the second memory cells at two programming pulse stages of the second memory cells. If the second memory cells are to be programmed to the L3 programmed state, the third voltage Vbl3 is applied to the L3 bit line coupled to the second memory cells at three programming pulse stages of the second memory cells.

Second, different voltages are applied to the bit lines coupled to the second memory cells to intervene a programming speed of the i−1 times of pulse programming by a manner of dividing the pulse programming into stages.

Optionally, in response to the second memory cells corresponding to the fast programming type, a fourth voltage Vbl4 is applied to the bit lines coupled to the second memory cells at a first stage of a kth pulse programming, and a fifth voltage Vbl5 is applied to the bit lines coupled to the second memory cells at a second stage of the kth pulse programming. A programming voltage is applied to the word lines coupled to the second memory cells to program the second memory cells to the ith programmed state, where the fourth voltage Vbl4 is higher than the fifth voltage Vbl5, where 0<k<i. In the case that the second memory cells correspond to the slow programming type, the fifth voltage Vbl5 is applied to the bit lines coupled to the second memory cells, and the programming voltage is applied to the word lines coupled to the second memory cells to perform the pulse programming for i−1 times to program the second memory cells to the ith programmed state.

Optionally, the first stage may be a stage before the second stage in the kth pulse programming, or a stage after the second stage in the kth pulse programming, or a stage comprising any multiple substages in the kth pulse programming. When the first stage is a stage comprising any multiple substages in the kth pulse programming, then the second stage is a stage comprising other substages than the multiple substages in the kth pulse program.

In some implementations of the present disclosure, description is made by taking the first stage being a stage before the second stage in the kth pulse programming as an example.

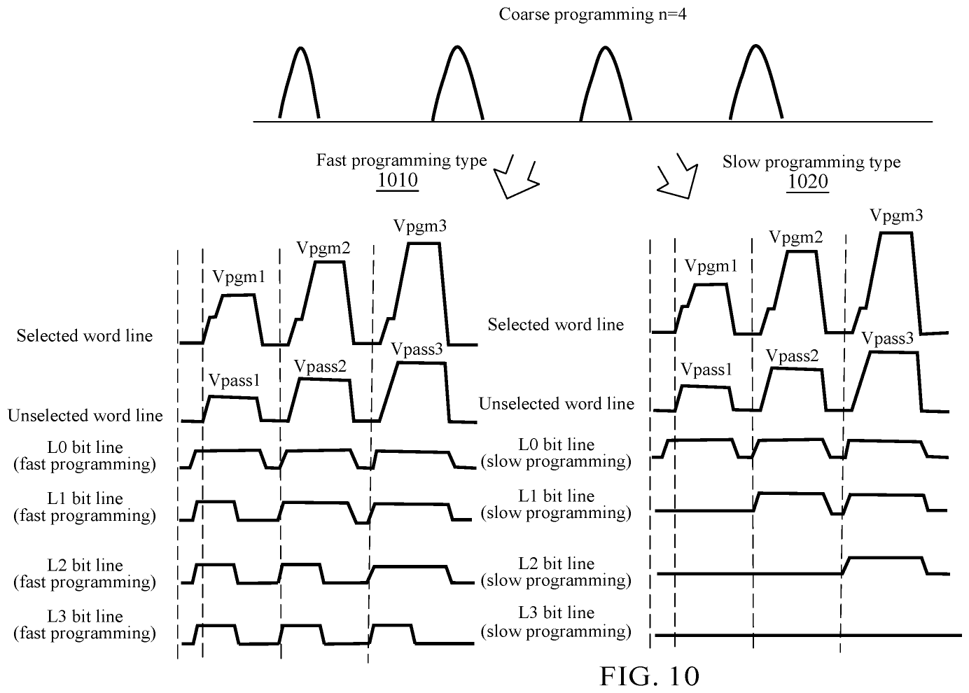

Referring to FIG. 10, when the second memory cells correspond to a fast programming type 1010, if the second memory cells are to be programmed to the L1 programmed state, then at a programming pulse stage of the second memory cells, a fourth voltage is applied to an L1 bit line coupled to the second memory cells at the first stage of the programming pulse stage, and a fifth voltage is applied to the L1 bit line coupled to the second memory cells at the second stage of the programming pulse stage. For example, the fourth voltage is Vbl4. Optionally, the fourth voltage Vbl4 is a voltage that causes the programming to be completely suppressed or almost completely suppressed, and the fifth voltage Vbl5 is a voltage that does not cause suppression to the programming, for example, 0 V. If the second memory cells are to be programmed to the L2 programmed state, then at two programming pulse stages of the second memory cells, the fourth voltage is applied to the L1 bit line coupled to the second memory cells at the first stage of each programming pulse stage, and the fifth voltage is applied to the L1 bit line coupled to the second memory cells at the second stage of each programming pulse stage. If the second memory cells are to be programmed to the L3 programmed state, then at three programming pulse stages of the second memory cells, the fourth voltage is applied to the L1 bit line coupled to the second memory cells at the first stage of each programming pulse stage, and the fifth voltage is applied to the L1 bit line coupled to the second memory cells at the second stage of each programming pulse stage.

When the second memory cells correspond to a slow programming type 1020, if the second memory cells are to be programmed to the L1 programmed state, the fifth voltage is applied to the L1 bit line coupled to the second memory cells at a programming pulse stage of the second memory cells. If the second memory cells are to be programmed to the L2 programmed state, the fifth voltage is applied to the L2 bit line coupled to the second memory cells at two programming pulse stages of the second memory cells. If the second memory cells are to be programmed to the L3 programmed state, the fifth voltage is applied to the L3 bit line coupled to the second memory cells at three programming pulse stages of the second memory cells.

In various implementations, in the coarse programming process, a pulse programming period of the memory cell corresponding to each programmed state is preset, the corresponding number of programming of the memory cell corresponding to each programmed state are distinguished, and the programming of the memory cells is completed without performing a verification operation on the voltage reached by the memory cells after each pulse programming in the coarse programming process. Thus, in some implementations, the programming method implementation omits the verification operation in the coarse programming to increase the efficiency of the coarse programming and reduce the time consumption of the coarse programming.

The method provided by this implementation applies one programming pulse and one (or more) verification operation(s) to other memory cells than the L0 memory cell before the coarse programming for the purpose of distinguishing the slow programming type and the fast programming type. Then, in the subsequent programming, with operations similar to the above, the programming verification is not performed any longer, but classified processing is performed for the fast programming type and the slow programming type. For the fast programming type, an intermediate voltage Vbla is applied to the bit line during the programming to suppress its programming speed, where a bit line voltage completely suppressing the programming is Vblb, and a bit line voltage not suppressing the programming is 0 V, where Vbla is greater than 0 V and less than Vblb. For the slow programming type, the voltage on the bit line during the programming is still 0 V. This can reduce a programmed state width after coarse programming and improve the reliability.

In the method provided by this implementation, for the fast programming type, its programming speed is controlled by a bit line timing. At an early stage of one programming pulse, the bit line voltage of the fast programming type is Vblb that is a voltage completely suppressing or almost completely suppressing the programming. At a later stage of one programming pulse, the bit line voltage of the fast programming type is reduced to 0 V for programming, thereby suppressing its programming speed.

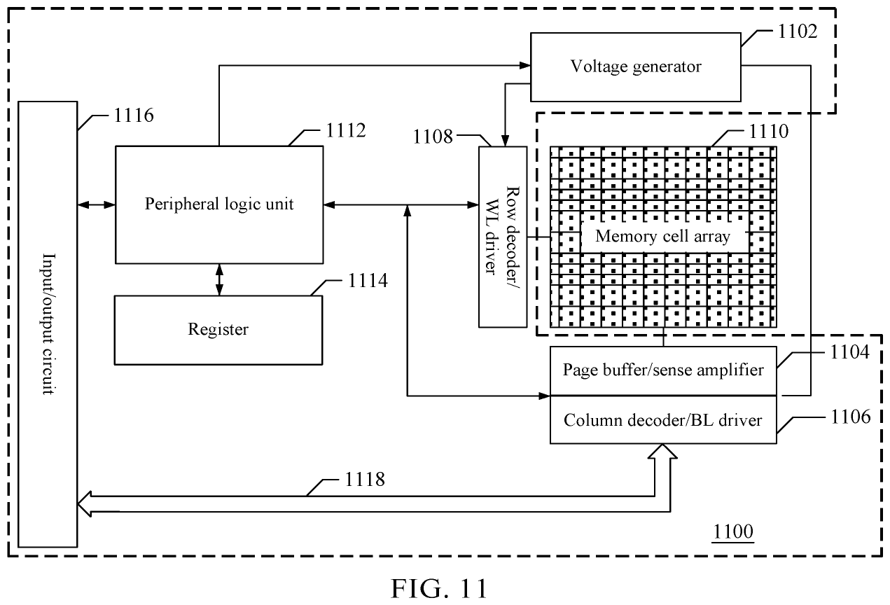

FIG. 11 is a schematic structural diagram of a memory provided by implementations of the present disclosure. As shown in FIG. 11, the memory comprises a peripheral circuit 1100 and a memory cell array 1110. The peripheral circuit 1100 is used to write and read data to and from the memory cell array 1110.

The peripheral circuit 1100 comprises a voltage generator 1102, a page buffer/sense amplifier 1104, a column decoder/bit line (BL) driver 1106, a row decoder/word line (WL) driver 1108, a peripheral logic unit 1112, a register 1114, an input/output circuit 1116 and a data bus 1118. In some examples, additional peripheral circuits 1100 not shown in FIG. 11 may be included as well.

The page buffer/sense amplifier 1104 may be configured to read and program (write) data from and to the memory cell array 1110 according to control signals from the peripheral logic unit 1112. In one example, the page buffer/sense amplifier 1104 may store one page of programming data (write data) to be programmed into one page of the memory cell array 1110. In another example, the page buffer/sense amplifier 1104 may perform programming verification operations to ensure that the data has been properly programmed into the memory cells coupled to the selected word lines. In yet another example, the page buffer/sense amplifier 1104 may also sense a low power signal from the bit lines that represents a data bit stored in the memory cells, and amplify a small voltage swing to a recognizable logic level in a read operation.

The column decoder/bit line driver 1106 may be configured to be controlled by the peripheral logic unit 1112 and select one or more NAND memory strings by applying bit line voltages generated from the voltage generator 1102.

The row decoder/word line driver 1108 may be configured to be controlled by the peripheral logic unit 1112 and select/unselect blocks of the memory cell array 1110 and select/unselect word lines of the blocks. The row decoder/word line driver 1108 may be further configured to drive the word lines using word line voltages (VWL) generated from the voltage generator 1102. In some implementations, the row decoder/word line driver 1108 may also select/unselect and drive source select gate lines and drain select gate lines. In some examples, the row decoder/word line driver 1108 is configured to perform erasing operations on the memory cells coupled to (one or more) selected word line(s).

The voltage generator 1102 may be configured to be controlled by the peripheral logic unit 1112 and generate a word line voltage (such as, a read voltage, a programming voltage, a pass voltage, a local voltage, a verification voltage, etc.), a bit line voltage and a source line voltage to be supplied to the memory cell array 1110.

The peripheral logic unit 1112 may be coupled to each peripheral circuit 1100 described above and configured to control the operations of each peripheral circuit 1100. The peripheral logic unit 1112 comprises a control circuit (not shown).

The register 1114 may be coupled to the peripheral logic unit 1112 and include, though not shown in FIG. 11, a state register, a command register, and an address register for storing state information, command operation codes (OP codes), and command addresses for controlling the operations of each peripheral circuit 1100. The input/output circuit 1116 may be coupled to the peripheral logic unit 1112, and act as a control buffer to buffer and relay control commands received from a host (not shown) to the peripheral logic unit 1112 and state information received from the peripheral logic unit 1112 to the host. The input/output circuit 1116 may also be coupled to the column decoder/bit line driver 1106 via a data bus 1118 and act as a data input/output interface and a data buffer to buffer and relay the data to and from the memory cell array 1110.

The peripheral circuit 1100 is configured to perform the programming method of the memory provided by the implementations of the present disclosure on selected rows of memory cells of a plurality of rows of memory cells, such as of the memory cell array 1110.

The memory as shown in FIG. 11 comprises a memory cell array 1110 and a peripheral circuit 1100, where the memory cell array 1110 comprises a plurality of blocks, and the blocks comprise memory cells. The peripheral circuit 1100 is configured to perform programming suppression on first memory cells of the memory cell array 1110 in the coarse programming process such that the first memory cells are in a first programmed state, and to perform pulse programming for i−1 times on second memory cells of the memory cell array 1110 in the coarse programming process to program the second memory cells to an ith programmed state, i>1, where the coarse programming process does not include programming verification.

In one optional implementation, the peripheral circuit 1100 is further configured to determine a number n of programmed states divided in the coarse programming process, n≥i; and apply programming pulses for n−1 times to a page in the memory based on the number n of the programmed states divided in the coarse programming process, where the first memory cells and the second memory cells are memory cells in the page.

In one optional implementation, the peripheral circuit 1110 is further configured to perform the pulse programming on the second memory cells at first i−1 programming pulses of the n−1 programming pulses to program the second memory cells to the ith programmed state.

In one optional implementation, the peripheral circuit 1110 is further configured to perform programming suppression on the second memory cells in a pulse programming process starting from an ith programming pulse in response to a number I of programming pulses applied to the page not reaching n−1.

In one optional implementation, the peripheral circuit 1110 is further configured to apply a first programming pulse to word lines coupled to memory cells in the page, perform programming verification on the memory cells in the page, and classify the memory cells into a fast programming type and a slow programming type based on a threshold voltage of the memory cells. The peripheral circuit 1110 is further configured to perform pulse programming for i−1 times on the second memory cells based on a memory cell type of the second memory cells to program the second memory cells to the ith programmed state.

In one optional implementation, the peripheral circuit 1110 is further configured to, in response to the second memory cells corresponding to the fast programming type, apply a second voltage to bit lines coupled to the second memory cells, and apply a programming voltage to word lines coupled to the second memory cells to perform the pulse programming for i−1 times to program the second memory cells to the ith programmed state. The peripheral circuit 1110 is further configured to, in response to the second memory cells corresponding to the slow programming type, apply a third voltage to bit lines coupled to the second memory cells, and apply a programming voltage to word lines coupled to the second memory cells to perform the pulse programming for i−1 times to program the second memory cells to the ith programmed state, wherein the second voltage is higher than the third voltage.

In one optional implementation, the peripheral circuit 1110 is further configured to, in response to the second memory cells corresponding to the fast programming type, apply a fourth voltage to bit lines coupled to the second memory cells at a first stage of a kth pulse programming, and apply a fifth voltage to the bit lines coupled to the second memory cells at a second stage of the kth pulse programming, and apply a programming voltage to word lines coupled to the second memory cells to program the second memory cells to the ith programmed state, where the fourth voltage is higher than the fifth voltage, and 0<k<i. The peripheral circuit 1110 is further configured to, in response to the second memory cells corresponding to the slow programming type, apply the fifth voltage to bit lines coupled to the second memory cells, and apply a programming voltage to word lines coupled to the second memory cells to perform the pulse programming for i−1 times to program the second memory cells to the ith programmed state.

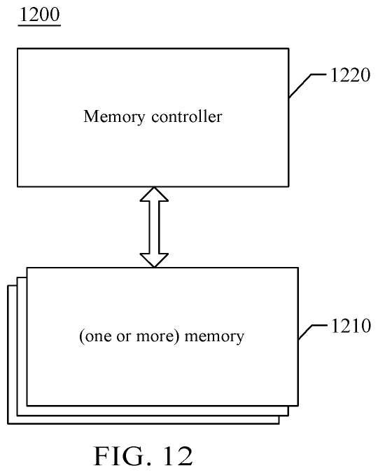

FIG. 12 is a structural block diagram of a storage system provided by one implementation of the present disclosure. As shown in FIG. 12, the storage system 1200 comprises one or more memories 1210, and a memory controller 1220 coupled to the memories 1210 and configured to control the memories 1210.

The storage system 1200 may be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic devices having memories 1210 therein.

Optionally, the storage system 1200 may comprise a host and a storage subsystem, where the storage subsystem has one or more memories 1210 and a memory controller 1220. The host may be a processor (e.g., a central processing unit (CPU)) or a system on chip (SOC) (e.g., an application processor (AP)) of an electronic device. The host may be configured to send data to the memories 1210. Alternatively, the host may be configured to receive data from the memories 1210.

According to some implementations, the memory controller 1220 is further coupled to the host. The memory controller 1220 can manage the data stored in memories 1210 and communicate with the host.

In some implementations, the memory controller 1220 is designed for operating in a low duty-cycle environment such as Secure Digital (SD) cards, Compact Flash (CF) cards, Universal Serial Bus (USB) flash drives, or other media for use in electronic devices, such as personal computers, digital cameras, mobile phones, etc.

In some implementations, the memory controller 1220 is designed for operating in high duty-cycle environment Solid-State Drives (SSD) or embedded Multi-Media Cards (eMMC) used as data memories for mobile devices, such as smartphones, tablets, laptop computers, etc., and enterprise arrays.

The memory controller 1220 may be configured to control operations of the memories 1210, such as reading, erasing, and programming operations. The memory controller 1220 may be further configured to manage various functions with respect to data stored or to be stored in the memories 1210, including, but not limited to bad-block management, garbage collection, logical-to-physical address conversion, wear leveling, etc. In some implementations, the memory controller 1220 is further configured to process error correction codes (ECC) with respect to the data read from or written to the memories 1210.

The memory controller 1220 may further perform any other suitable functions as well, for example, formatting the memories 1210. The memory controller 1220 may communicate with an external device according to a particular communication protocol.

The memory controller 1220 and the one or more memories 1210 can be integrated into various types of storage devices, for example, be included in the same package, such as a Universal Flash Storage (UFS) package or an eMMC package. For example, the memory system 1200 can be implemented and packaged into different types of terminal electronic products.

The memory controller 1220 and a single memory 1210 may be integrated into a memory card. The memory card may include a PC card (PCMCIA, Personal Computer Memory Card International Association), a CF card, a Smart Media (SM) card, a memory stick, a Multi-media card (MMC, RS-MMC, MMCmicro), an SD card (SD, miniSD, microSD, SDHC), a UFS, etc. The memory card may further include a memory card connector coupling the memory card with the host.

The memory controller 1220 and multiple memories 1210 may be integrated into a SSD. In some implementations, the storage capacity and/or the operation speed of the solid-state drive are greater than those of the memory card.

The memory controller 1220 may perform the programming method of the memory provided by any of the implementations of the present disclosure.

Implementations of the present disclosure provide a control circuit which comprises a programmable logic circuit and/or a program instruction, where the control circuit may be used to achieve the programming method of the memory provided by the preceding implementations of the present disclosure. A programming operation includes coarse programming and fine programming.

Implementations of the present disclosure provide a computer readable storage medium which stores instructions therein, where the instructions achieve the programming method of the memory provided by the preceding implementations of the present disclosure when controlling running on a circuit.

In the present disclosure, the terms “first” and “second” are only for the purpose of description, and cannot be construed as indicating or implying relative importance. The term “at least one” means one or more, and the term “a plurality of” means two or more, unless otherwise defined clearly.

The term “and/or” in the present disclosure is only an association relationship for describing associated objects, and means that three relationships may exist. For example, A and/or B may represent the presence of A alone, the presence of A and B simultaneously, and the presence of B alone. In addition, the character “/” herein generally means that associated objects before and after it have a relationship of “or”.

The above descriptions are only implementations of the present disclosure, and are not used to limit the present disclosure. Any amendments, equivalent substitutions and improvements and the like made to the present disclosure, as long as within the spirits and principles of the present disclosure, shall be encompassed within the protection scope of the present disclosure.

What is claimed is:

1. A method of programming a memory, through a programming operation having a coarse programming process and a fine programming process, the method comprising:
performing programming suppression on first memory cells in the coarse programming process, such that the first memory cells are in a first programmed state; and
performing pulse programming for i−1 times on second memory cells to program the second memory cells to an ith programmed state in the coarse programming process, where i>1,
wherein the coarse programming process does not include programming verification.

2. The method of claim 1, further comprising:
determining a number n of programmed states divided in the coarse programming process, where n≥i; and
applying programming pulses for n−1 times to a page in the memory based on the number n of the programmed states divided in the coarse programming process, the first memory cells and the second memory cells being memory cells in the page.

3. The method of claim 2, wherein performing the pulse programming for i−1 times on the second memory cells to program the second memory cells to the ith programmed state comprises performing the pulse programming on the second memory cells at first i−1 programming pulses of the n−1 programming pulses to program the second memory cells to the ith programmed state.

4. The method of claim 3, further comprising, in response to a number i of programming pulses applied to the page not reaching n−1, performing programming suppression on the second memory cells in a pulse programming process starting from an ith programming pulse.

5. The method of claim 2, wherein prior to performing the pulse programming for n−1 times on the page in the memory based on the number n of the programmed states divided in the coarse programming process, the method further comprises:
applying a first voltage to word lines coupled to the memory cells in the page;
performing programming verification on the memory cells in the page; and
classifying the memory cells into a fast programming type and a slow programming type based on a threshold voltage of the memory cells, and
wherein performing the pulse programming for i−1 times on the second memory cells to program the second memory cells to the ith programmed state comprises performing the pulse programming for i−1 times on the second memory cells to program the second memory cells to the ith programmed state based on a memory cell type of the second memory cells.

6. The method of claim 5, wherein performing the pulse programming for i−1 times on the second memory cells to program the second memory cells to the ith programmed state based on the memory cell type of the second memory cells comprises:
in response to the second memory cells corresponding to the fast programming type, applying a second voltage to bit lines coupled to the second memory cells, and applying a programming voltage to word lines coupled to the second memory cells to perform the pulse programming for i−1 times to program the second memory cells to the ith programmed state; and
in response to the second memory cells corresponding to the slow programming type, applying a third voltage to bit lines coupled to the second memory cells, and applying the programming voltage to word lines coupled to the second memory cells to perform the pulse programming for i−1 times to program the second memory cells to the ith programmed state,
wherein the second voltage is higher than the third voltage.

7. The method of claim 5, wherein performing the pulse programming for i−1 times on the second memory cells to program the second memory cells to the ith programmed state based on the memory cell type of the second memory cells comprises:
in response to the second memory cells corresponding to the fast programming type, applying a fourth voltage to bit lines coupled to the second memory cells at a first stage of a kth pulse programming, and applying a fifth voltage to the bit lines coupled to the second memory cells at a second stage of the kth pulse programming, and applying a programming voltage to word lines coupled to the second memory cells to program the second memory cells to the ith programmed state, the fourth voltage being higher than the fifth voltage, where 0<k<i; and
in response to the second memory cells corresponding to the slow programming type, applying the fifth voltage to bit lines coupled to the second memory cells, and applying the programming voltage to word lines coupled to the second memory cells to perform the pulse programming for i−1 times to program the second memory cells to the ith programmed state.

8. A memory programmable by a programming operation having coarse programming and fine programming, the memory comprising: an array and a peripheral circuit,
wherein the peripheral circuit is configured to:
perform programming suppression on first memory cells of the array in the coarse programming process, such that the first memory cells are in a first programmed state; and
perform pulse programming for i−1 times on second memory cells of the array to program the second memory cells to an ith programmed state in the coarse programming process, where i>1, and
wherein the coarse programming process does not include programming verification.

9. The memory of claim 8, wherein the peripheral circuit is further configured to:
determine a number n of programmed states divided in the coarse programming process, where n≥i; and
apply programming pulses for n−1 times to a page in the memory based on the number n of the programmed states divided in the coarse programming process, the first memory cells and the second memory cells being memory cells in the page.

10. The memory of claim 9, wherein the peripheral circuit is further configured to perform the pulse programming on the second memory cells at first i−1 programming pulses of the n−1 programming pulses to program the second memory cells to the ith programmed state.

11. The memory of claim 10, wherein the peripheral circuit is further configured to, in response to a number i of programming pulses applied to the page not reaching n−1, perform programming suppression on the second memory cells in a pulse programming process starting from an ith programming pulse.

12. The memory of claim 9, wherein the peripheral circuit is further configured to:
apply a first programming pulse to word lines coupled to memory cells in the page; perform programming verification on the memory cells in the page; and classify the memory cells into a fast programming type and a slow programming type based on a threshold voltage of the memory cells; and
perform the pulse programming for i−1 times on the second memory cells to program the second memory cells to the ith programmed state based on a memory cell type of the second memory cells.

13. The memory of claim 12, wherein the peripheral circuit is further configured to, in response to the second memory cells corresponding to the fast programming type, apply a second voltage to bit lines coupled to the second memory cells, and apply a programming voltage to word lines coupled to the second memory cells to perform the pulse programming for i−1 times to program the second memory cells to the ith programmed state; and
in response to the second memory cells corresponding to the slow programming type, apply a third voltage to bit lines coupled to the second memory cells, and apply the programming voltage to word lines coupled to the second memory cells to perform the pulse programming for i−1 times to program the second memory cells to the ith programmed state;
wherein the second voltage is higher than the third voltage.

14. The memory of claim 12, wherein the peripheral circuit is further configured to, in response to the second memory cells corresponding to the fast programming type, apply a fourth voltage to bit lines coupled to the second memory cells at a first stage of a kth pulse programming, and apply a fifth voltage to the bit lines coupled to the second memory cells at a second stage of the kth pulse programming, and apply a programming voltage to word lines coupled to the second memory cells to program the second memory cells to the ith programmed state, the fourth voltage being higher than the fifth voltage, where 0<k<i; and
in response to the second memory cells corresponding to the slow programming type, apply the fifth voltage to bit lines coupled to the second memory cells, and apply the programming voltage to word lines coupled to the second memory cells to perform the pulse programming for i−1 times to program the second memory cells to the ith programmed state.

15. A system, comprising:
one or more memories programmable by a programming operation having coarse programming and fine programming, the memories comprising:
an array; and
a peripheral circuit, wherein the peripheral circuit is configured to:
perform programming suppression on first memory cells of the array in the coarse programming process, such that the first memory cells are in a first programmed state; and
perform pulse programming for i−1 times on second memory cells of the array to program the second memory cells to an ith programmed state in the coarse programming process, where i>1, and
wherein the coarse programming process does not include programming verification; and
a memory controller coupled to the memories and configured to control the memories.

16. The system of claim 15, wherein the peripheral circuit is further configured to:
determine a number n of programmed states divided in the coarse programming process, where n≥i; and
apply programming pulses for n−1 times to a page in the memory based on the number n of the programmed states divided in the coarse programming process, the first memory cells and the second memory cells being memory cells in the page.

17. The system of claim 16, wherein the peripheral circuit is further configured to:
perform the pulse programming on the second memory cells at first i−1 programming pulses of the n−1 programming pulses to program the second memory cells to the ith programmed state; and
in response to a number i of programming pulses applied to the page not reaching n−1, perform programming suppression on the second memory cells in a pulse programming process starting from an ith programming pulse.

18. The system of claim 17, wherein the peripheral circuit is further configured to:
apply a first programming pulse to word lines coupled to memory cells in the page; perform programming verification on the memory cells in the page; and classify the memory cells into a fast programming type and a slow programming type based on a threshold voltage of the memory cells; and
perform the pulse programming for i−1 times on the second memory cells to program the second memory cells to the ith programmed state based on a memory cell type of the second memory cells.

19. The system of claim 18, wherein the peripheral circuit is further configured to:
in response to the second memory cells corresponding to the fast programming type, apply a second voltage to bit lines coupled to the second memory cells, and apply a programming voltage to word lines coupled to the second memory cells to perform the pulse programming for i−1 times to program the second memory cells to the ith programmed state; and
in response to the second memory cells corresponding to the slow programming type, apply a third voltage to bit lines coupled to the second memory cells, and apply the programming voltage to word lines coupled to the second memory cells to perform the pulse programming for i−1 times to program the second memory cells to the ith programmed state;
wherein the second voltage is higher than the third voltage.

20. The system of claim 18, wherein the peripheral circuit is further configured to:
in response to the second memory cells corresponding to the fast programming type, apply a fourth voltage to bit lines coupled to the second memory cells at a first stage of a kth pulse programming, and apply a fifth voltage to the bit lines coupled to the second memory cells at a second stage of the kth pulse programming, and apply a programming voltage to word lines coupled to the second memory cells to program the second memory cells to the ith programmed state, the fourth voltage being higher than the fifth voltage, where 0<k<i; and
in response to the second memory cells corresponding to the slow programming type, apply the fifth voltage to bit lines coupled to the second memory cells, and apply the programming voltage to word lines coupled to the second memory cells to perform the pulse programming for i−1 times to program the second memory cells to the ith programmed state.
